(19) United States
(12) Patent Application Publication
(10) Pub. No.: US 2025/0301784 A1
(43) Pub. Date: Sep. 25, 2025

(54) SEMICONDUCTOR DEVICE AND METHOD FOR FORMING THE SAME

(71) Applicants: TAIWAN SEMICONDUCTOR MANUFACTURING COMPANY, LTD., Hsinchu (TW); NATIONAL TSING HUA UNIVERSITY, HSINCHU CITY (TW)

(72) Inventors: Yung-Chun WU, Hsinchu City (TW); Fu-Ju HOU, Chiayi County (TW); Yi-Wen LIN, Pingtung County (TW); Shan-Wen LIN, Pingtung County (TW)

(73) Assignees: TAIWAN SEMICONDUCTOR MANUFACTURING COMPANY, LTD., Hsinchu (TW); NATIONAL TSING HUA UNIVERSITY, HSINCHU CITY (TW)

(21) Appl. No.: 18/611,610

(22) Filed: Mar. 20, 2024

(51) Int. Cl. H01L 27/092; H01L 21/265; H01L 21/3065; H01L 21/822; H01L 21/8238; H01L 29/06; H01L 29/423; H01L 29/66; H01L 29/775

(52) U.S. Cl. CPC H10D 84/856; H01L 21/26513; H01L 21/3065; H10D 30/014; H10D 30/43; H10D 30/6735; H10D 62/121; H10D 84/0167; H10D 84/017; H10D 84/038; H10D 88/01

(57) ABSTRACT

A method includes forming a second semiconductor layer over a first semiconductor layer; performing a first etching process to form a recess in the second semiconductor layer, such that the second semiconductor layer includes a bottom portion and a top portion over the bottom portion, wherein the first etching process results in forming first dielectric layers on opposite sidewalls of the top portion; performing a second etching process to narrow the bottom portion of the second semiconductor layer; performing a third etching process to remove the bottom portion of the second semiconductor layer; performing a fourth etching process to narrow the first semiconductor layer; and forming a first gate structure over the first semiconductor layer and a second gate structure over the second semiconductor layer, respectively.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 16D illustrate a method in various stages of forming a semiconductor device in accordance with some embodiments of the present disclosure.

FIG. 17 is a cross-sectional view of a semiconductor device in accordance with some embodiments of the present disclosure.

FIGS. 18 to 24D illustrate a method in various stages of forming a semiconductor device in accordance with some embodiments of the present disclosure.

FIGS. 25A and 25B are simulation results of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated.

One skilled in the art will realize, however, that the values or ranges recited throughout the description are merely examples, and may be reduced or varied with the down-scaling of the integrated circuits.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In the present disclosure, a complementary FET (CFET) is provided, and its manufacturing method will be disclosed in the following discussion. In a CFET, a first transistor is disposed over a substrate (not shown), and a second transistor is disposed vertically above the first transistor. In some embodiments, the first transistor and the second transistor may be field effect transistor (FET). The first transistor may include a fin-type configuration, and thus the first transistor can be also referred to as a FinFET. On the other hand, the second transistor may include a gate-all-around (GAA) configuration, and thus the second transistor can also be referred to as a GAA FET.

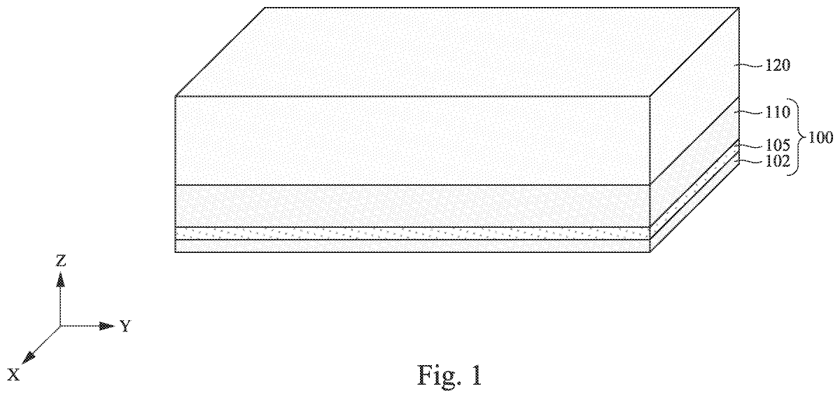

FIGS. 1 to 16D illustrate a method in various stages of forming a semiconductor device in accordance with some embodiments of the present disclosure. Although FIGS. 1 to 16D are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a substrate 100. In some embodiments, the substrate 100 may be a silicon-on-insulator (SOI) substrate. For example, the substrate 100 is an SOI substrate including a bulk semiconductor layer 102, a dielectric layer 105 over the bulk semiconductor layer 102, and a semiconductor layer 110 over the dielectric layer 105. In some embodiments, the dielectric layer 105 may be a buried oxide (BOX) layer formed by a process such as separation by implanted oxygen (SIMOX), and/or other suitable processes. In some embodiments, the BOX layer is a silicon dioxide (SiO2) layer. The semiconductor layer 110 may include silicon.

A semiconductor layer 120 is formed over the substrate 100 and in contact with the top surface of the semiconductor layer 110 of the substrate 100. The semiconductor layer 120 may include different semiconductor material than the semiconductor layer 110. In greater detail, the semiconductor layer 110 may include a semiconductor material suitable for an n-type device, and the semiconductor layer 120 may include a semiconductor material suitable for a p-type device, while the present disclosure is not limited thereto. In some embodiments, the semiconductor layer 110 may be made of silicon (Si), and the semiconductor layer 120 may be made of germanium (Ge). In some embodiments, the semiconductor layer 110 may be made of substantially pure silicon layer, for example, with a silicon percentage greater than about 98 percent. Similarly, the semiconductor layer 120 may be made of substantially pure germanium layer, for example, with a germanium percentage greater than about 98 percent.

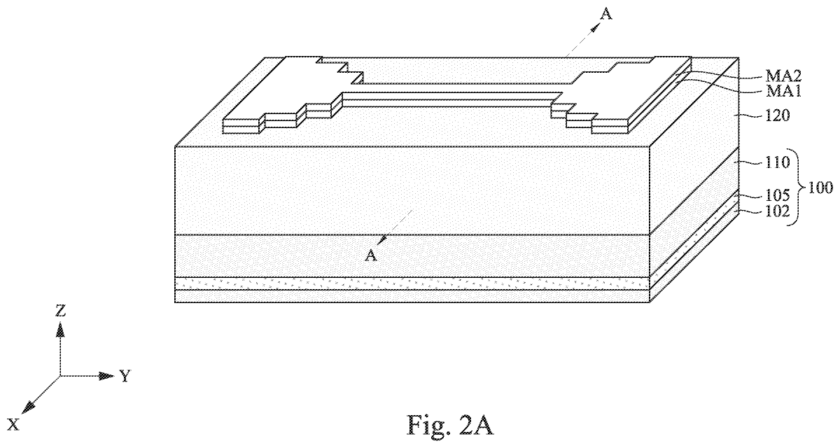

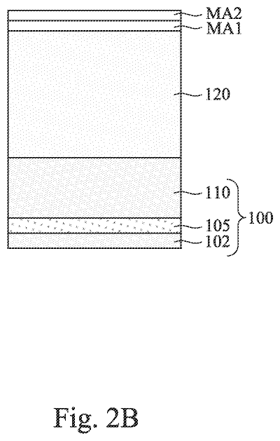

Reference is made to FIGS. 2A and 2B, in which FIG. 2A is a schematic view of a semiconductor device, and FIG. 2B is a cross-sectional view along line A-A of FIG. 2A. A mask MA1 is formed over the semiconductor layer 120, and a mask MA2 is formed over the mask MA1. The mask MA2 may be patterned using suitable lithography process, and the mask MA1 is then patterned using the patterned mask MA2. The patterned masks MA1 and MA2 may be used to define active regions over the substrate 100. In some embodiments, the mask MA1 may be a hard mask, and may be made of suitable material, such as oxide or nitride. For example, the mask MA1 may be made of silicon oxide using PECVD. The silicon oxide hard mask can prevent the underlying germanium layer (e.g., semiconductor layer 120) be oxidized. On the other hand, the mask MA2 may be a photoresist layer.

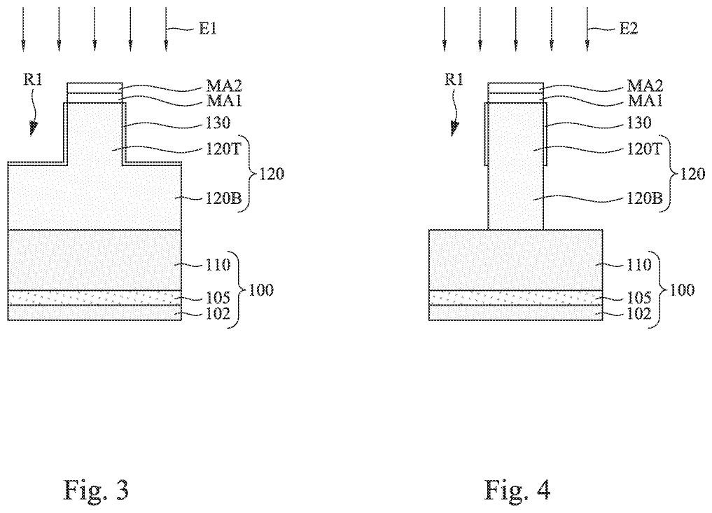

FIGS. 3-6 illustrate processes for defining active regions over the substrate 100 using the patterned masks MA1 and MA2. In greater detail, FIGS. 3-6 illustrate performing several etching processes to remove portions of the semiconductor layers 110 and 120 by using the patterned masks MA1 and MA2 as etch mask, so as to define active regions over the substrate 100.

Reference is made to FIG. 3, in which FIG. 3 is a cross-sectional view that follows the cross-sectional view of FIG. 2B. A first etching process El is performed to remove portions of the semiconductor layer 120 that are exposed through the masks MA1 and MA2, so as to form recesses R1 in the semiconductor layer 120. As a result of the first etching process El, the etched semiconductor layer 120 may include a top portion 120T and a bottom portion 120B under the top portion 120T, in which the bottom portion 120B is wider than the top portion 120T in the cross-sectional view of FIG. 3. From a different perspective, the top portion 120T may be referred to as a protrusion portion that protrudes upward from the bottom portion 120B.

The first etching process El may be an anisotropic etching process. In some embodiments, the first etching process El may be dry etch, such as reactive ion etching (RIE) process, while other suitable etching process may also be employed. In some embodiments, the reaction gas of the first etching process El may include chlorine (Cl₂) and oxygen (0₂). Chlorine (Cl₂) may serve as the etchant for etching the semiconductor layer 120. In some embodiments, the first etching process El may be performed under a pressure of about 5 mTorr to about 30 mTorr, a power of about 200 W to about 900 W, a bias voltage of about 250 V to about 500 V, at a temperature of about 45° C. to about 60° C.

On the other hand, during the first etching process El, oxygen (0₂) may react with surface portions of the semiconductor layer 120 to form oxide layers 130 on the exposed surfaces of the semiconductor layer 120 as a byproduct of the first etching process El. That is, the oxide layers 130 may line the surfaces of the recesses R1. In greater detail, the oxide layers 130 may line the sidewalls of the top portion 120T of the semiconductor layer 120 and the top surface of the bottom portion 120B of the

semiconductor layer 120. The oxide layers 130 may be an oxide of the material of the semiconductor layer 120. For example, when the semiconductor layer 120 is made of germanium (Ge), the oxide layers 130 may be germanium oxide (GeO₂). In some embodiments, the oxide layers 130 can also be referred to as a dielectric layer.

Reference is made to FIG. 4, in which FIG. 4 is a cross-sectional view that follows the cross-sectional view of FIG. 3. After the first etching process El is complete, a second etching process E2 is performed to remove horizontal portions of the oxide layers 130 to expose the bottom portion 120B of the semiconductor layer 120. Once the horizontal portions of the oxide layers 130 are removed, the second etching process E2 removes the exposed bottom portion 120B of the semiconductor layer 120 so as to narrow the bottom portion 120B of the semiconductor layer 120. In some embodiments, the second etching process E2 is performed until the underlying semiconductor layer 110 is exposed.

The second etching process E2 may be an anisotropic etching process. In some embodiments, the second etching process E2 may be dry etch, such as reactive ion etching (RIB) process, while other suitable etching process may also be employed. In some embodiments, the reaction gas of the second etching process E2 may include chlorine (C1₂). Chlorine (Cl₂) may serve as the etchant for etching the semiconductor layer 120. The second etching process E2 is different from the first etching process El, in that the reaction gas of the second etching process E2 does not include oxygen (0₂). In some embodiments, the second etching process E2 may be performed under a pressure of about 5 mTorr to about 30 mTorr, a power of about 200 W to about 900 W, a bias voltage of about 250 V to about 500 V, at a temperature of about 45° C. to about 60° C.

As mentioned above, because the second etching process E2 is an anisotropic etching process, the second etching process E2 may remove the horizontal portions of the oxide layers 130. Because chlorine (C1₂) has lower etching rate on oxide material, and thus vertical portions of the oxide layers 130 may remain on the sidewalls of the top portion 120T of the semiconductor layer 120. The remaining oxide layers 130 may serve as protective layers to protect the top portion 120T of the semiconductor layer 120 during the following etching processes.

Moreover, because the reaction gas of the second etching process E2 does not include oxygen (0₂), aside from the existed oxide layers 130, no oxide layer is formed over the semiconductor surface (e.g., semiconductor layers 110 and 120) once the second etching process E2 is complete. Stated another way, the sidewalls of the bottom portion 120B of the semiconductor layer 120 and the top surface of the semiconductor layer 110 remain exposed through the recesses R1 after the second etching process E2 is complete.

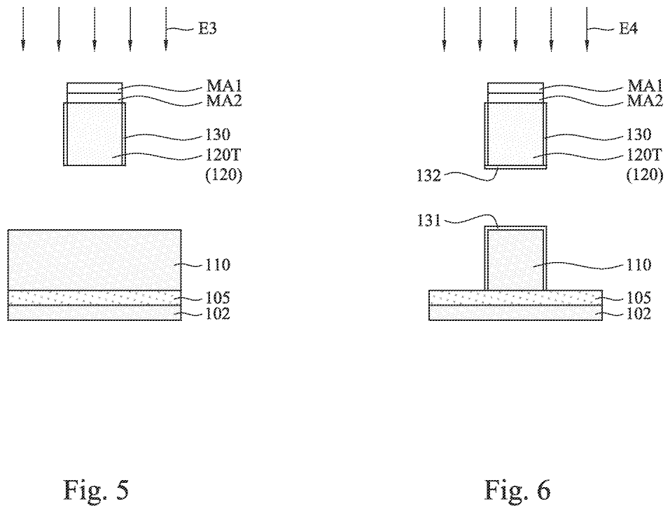

Reference is made to FIG. 5, in which FIG. 5 is a cross-sectional view that follows the cross-sectional view of FIG. 4. After the second etching process E2 is complete, a third etching process E3 is performed to remove the bottom portion 120B of the semiconductor layer 120. On the other hand, the oxide layers 130 may protect the top portion 120T of the semiconductor layer 120 to prevent the top portion 120T of the semiconductor layer 120 from damage during the third etching process E3. As a result of the third etching process E3, the semiconductor layer 120 is vertically separated from the semiconductor layer 110. Stated another way, the third etching process E3 is performed such that a gap is formed vertically between the semiconductor layer 120 and the semiconductor layer 110.

The third etching process E3 may be an isotropic etching process. In some embodiments, the third etching process E3 may be isotropic dry etch, such as reactive ion etching (RIB) process, while other suitable etching process may also be employed. In some embodiments, the reaction gas of the third etching process E3 may include chlorine (Cl₂) and hydrogen bromide (HBr). Chlorine (Cl₂) and hydrogen bromide (HBr) both may serve as the etchant for etching the semiconductor layer 120. In some embodiments, the third etching process E3 is different from first etching process El and the second etching process E2, in that the third etching process E3 includes hydrogen bromide (HBr). The use of hydrogen bromide (HBr) may provide isotropy property for the etching process, this is because hydrogen bromide (HBr) may include higher etching

rate to the material of the semiconductor layer 120 (e.g., Ge) than to the material of the semiconductor layer 110 (e.g., Si). In some embodiments, the semiconductor layer 110 may keep substantially intact or negligibly etched during the third etching process E3. In some embodiments, the third etching process E3 may be performed under a pressure of about 5 mTorr to about 30 mTorr, a power of about 200 W to about 900 W, a bias voltage of about 0 V to about 500 V (e.g., OV means no bias is applied), at a temperature of about 45° C. to about 60° C.

Reference is made to FIG. 6, in which FIG. 6 is a cross-sectional view that follows the cross-sectional view of FIG. 6. After the third etching process E3 is complete, a fourth etching process E4 is performed to remove portions of the semiconductor layer 110 exposed through the top portion 120T of the semiconductor layer 120 (or the masks MA1 and MA2), so as to narrow the semiconductor layer 110. After the fourth etching process E4 is complete, the remaining portion of the semiconductor layer 110 is vertically below the semiconductor layer 120.

The fourth etching process E4 may be an anisotropic etching process. In some embodiments, the fourth etching process E4 may be dry etch, such as reactive ion etching (RIB) process, while other suitable etching process may also be employed. In some embodiments, the reaction gas of the fourth etching process E4 may include chlorine (C1₂) and oxygen (0₂). Chlorine (Cl₂) may serve as the etchant for etching the semiconductor layer 120. In some embodiments, the fourth etching process E4 may be performed under a pressure of about 5 mTorr to about 30 mTorr, a power of about 200 W to about 900 W, a bias voltage of about 250 V to about 500 V, at a temperature of about 45° C. to about 60° C.

On the other hand, during the fourth etching process E4, oxygen (0₂) may react with surface portions of the semiconductor layer 120 and the semiconductor layer 110 to form oxide layers 131 and 132 respectively on the exposed surfaces of the semiconductor layer 110 and the semiconductor layer 120 as byproduct of the fourth etching process E4. In greater detail, the oxide layer 131 may line the sidewalls and the top surface of the semiconductor layer 110, and the oxide layer 132 may line the bottom surface of the semiconductor layer 120. No additional oxide layer is formed on the sidewalls of the semiconductor layer 120 because they are already covered by the oxide layers 130. The oxide layer 131 may be an oxide of the material of the semiconductor layer 110, and the oxide layer 132 may be an oxide of the material of the semiconductor layer 120. For example, when the semiconductor layer 110 is made of silicon (Si), the oxide layer 131 may be silicon oxide (SiO2)· When the semiconductor layer 120 is made of germanium (Ge), the oxide layer 132 may be germanium oxide (GeO2)· The oxide layers 130 and 132 may be made of a same material that is different from the material of the oxide layer 131. In some embodiments, the oxide layers 131 and 132 can also be referred to as a dielectric layer.

Based on the above discussion, the first etching process El, the second etching process E2, the third etching process E3, and the etching process E4 include using chlorine (C1₂) as etching gas. The first etching process El and the fourth etching process E4 further include using oxygen (0₂) for forming the oxide layers 130, 131, and 132, while the second etching process E2 and the third etching process E3 may be free of using oxygen (0₂). The third etching process E3 further includes using hydrogen bromide (HBr) to provide isotropic etching property, while the first etching process El, the second etching process E2, and the etching process E4 may be free of using hydrogen bromide (HBr), and thus the first etching process El, the second etching process E2, and the etching process E4 may include anisotropic etching property.

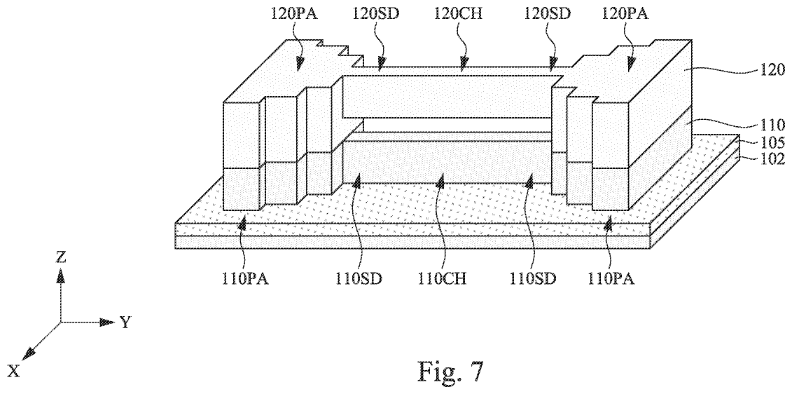

Reference is made to FIG. 7, in which FIG. 7 is a schematic view of a semiconductor device. As mention above, the structure of FIG. 2A may undergo the etching processes as discussed in FIGS. 3 to 6. After the etching processes are complete, the masks MA1 and MA2 are removed from the top surface of the semiconductor layer 120. Moreover, a pre-clean process is performed to remove the oxide layers 130, 131, and 132, such that surfaces of the semiconductor layers 110 and 120 are exposed, and the resulting structure is shown in FIG. 7. As discussed, the semiconductor layers 110 and 120 are patterned to form active regions. In some embodiments, the patterned semiconductor layer 110 can be referred to as a fin structure over the dielectric layer 105,

and the patterned semiconductor layer 120 can be referred to as a nanowire stacked vertically above the patterned semiconductor layer 110.

With respect to the patterned semiconductor layer 110, the patterned semiconductor layer 110 include a channel region 110CH, source/drain regions 110SD on opposite sides of the channel region 110CH, and pad regions 110PA connected with the respective source/drain regions 110SD. Thus, the source/drain regions 110SD and the pad regions 110PA may collectively serve as source/drain structures of a semiconductor device. In some embodiments, the pad regions 110PA each may include a greater area than the source/drain regions 110SD. Similarly, with respect to the patterned semiconductor layer 120, the patterned semiconductor layer 120 include a channel region 120CH, source/drain regions 120SD on opposite sides of the channel region 120CH, and pad regions 120PA connected with the respective source/drain regions 120SD. In some embodiments, the pad regions 120PA each may include a greater area than the source/drain regions 120SD. In some embodiments, the pad regions 120PA may be in contact with the pad regions 110PA, this is because the pad regions 120PA include larger area, and the etching processes described in FIGS. 4-6 may not etch through the pad regions 120PA. In some embodiments, the pad regions 120PA of the patterned semiconductor layer 120 may be removed in the following processes.

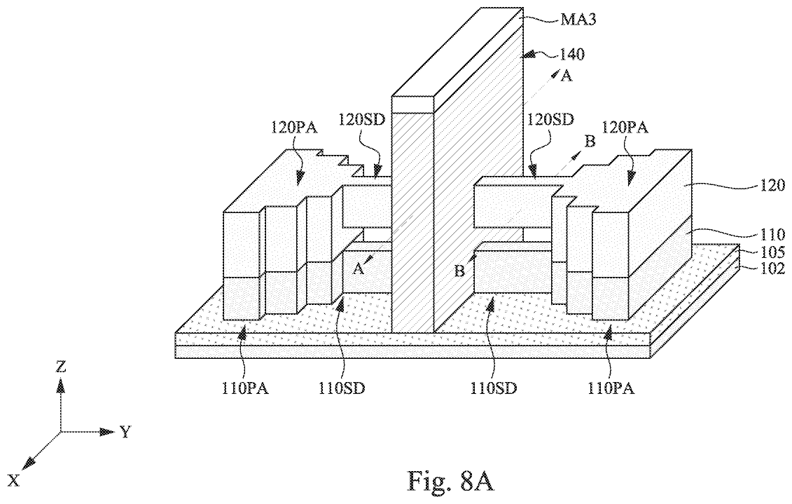

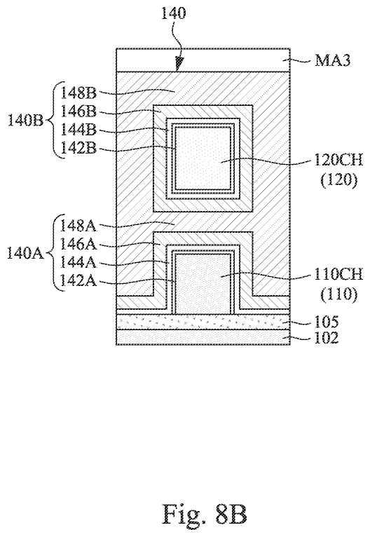

Reference is made to FIGS. 8A and 8B, in which FIG. 8A is a schematic view of a semiconductor device, and FIG. 8B is a cross-sectional view along line A-A of FIG. 8A. It is noted that some elements of FIG. 8B are not illustrated in FIG. 8A for brevity. A gate stack 140 is formed over the substrate 100, crossing the channel region 110CH of the semiconductor layer 110 and wrapping around the channel region 120CH of the semiconductor layer 120. In some embodiments, a mask MA3 may be used to define the profile and the position of the gate stack 140.

As shown in FIG. 8B, the gate stack 140 includes a first gate structure 140A and a second gate structure 140B over the gate structure 140A. In greater detail, the first gate structure 140A may be referred to as the portion of the gate stack 140 that crosses the channel region 110CH of the semiconductor layer 110, and the second gate structure

140B may be referred to as the portion of the gate stack 140 that wraps around the channel region 120CH of the semiconductor layer 120. In some embodiments, the gate structure 140A may be in contact with three sides (e.g., top surface and opposite sidewalls) of the semiconductor layer 110. The gate structure 140B may be in contact with four sides (e.g., top surface, bottom surface, and opposite sidewalls) of the semiconductor layer 120.

With respect to the first gate structure 140A, the first gate structure 140A includes an interfacial layer 142A, a high-k dielectric layer 144A over the interfacial layer 142A, a work function metal layer 146A over the high-k dielectric layer 144A, and a filling metal 148A over the work function metal layer 146A. With respect to the second gate structure 140B, the second gate structure 140B includes an interfacial layer 142B, a high-k dielectric layer 144B over the interfacial layer 142B, a work function metal layer 146B over the high-k dielectric layer 144B, and a filling metal 148B over the work function metal layer 146B. In some embodiments, the filling metal 148A and the filling metal 148B may be different portions of a single piece material.

The gate stack 140 may be formed by, for example, performing an oxidation process to form the interfacial layer 142A selectively on the exposed surfaces of the semiconductor layer 110 and the interfacial layer 142B selectively on the exposed surfaces of the semiconductor layer 120. For example, the oxidation process may include using ozone (0₃) plasma in an ALD chamber to form the interfacial layers 142A and 142B. Thus, the interfacial layer 142A may be an oxide of the material of the semiconductor layer 110, and the interfacial layer I42B may be an oxide of the material of the semiconductor layer 120. In some embodiments where the semiconductor layers 110 and 120 are made of silicon (Si) and germanium (Ge), respectively, the interfacial layers 142A and 142B may be made of silicon oxide (SiO₂) and germanium oxide (Ge0₂), respectively. That is, when the semiconductor layers 110 and 120 are made of different materials, the interfacial layers 142A and 142B may include different materials.

After the interfacial layers 142A and 142B are formed, a deposition process is performed to form the high-k dielectric layers 144A and 144B over the interfacial layers 142A and 142B, respectively. The high-k dielectric layer 144A may extend to top surface of the dielectric layer 105. In some embodiments, the deposition process may be a conformal deposition process, such as chemical vapor deposition (CVD), atomic layer deposition (ALD), or the like. Examples of high-k dielectric material include aluminum oxide (A1203), hafnium oxide _{(HfO2),} hafnium silicon oxide (HfSiO), hafnium silicon oxynitride (HfSiON), hafnium tantalum oxide (HfTa0), hafnium titanium oxide (HfTiO), hafnium zirconium oxide (HfZrO), zirconium oxide (ZrO), titanium oxide (TiO), hafnium dioxide-alumina (Hf0₂-A1₂0₃) alloy, other suitable high-k dielectric materials, and/or combinations thereof.

After the high-k dielectric layers 144A and 144B are formed, a deposition process is performed to form the work function metal layers 146A and 146B over the high-k dielectric layers 144A and 144B, respectively. In some embodiments, the deposition process may include physical vapor deposition (PVD), chemical vapor deposition (CVD), atomic layer deposition (ALD), or the like. In some embodiments, the work function metal layers 146A and 146B may include tantalum nitride (TaN). In other embodiments, the work function metal layers 146A and 146B may also include titanium (Ti), titanium nitride (TiN), tantalum (Ta), tantalum nitride (TaN), titanium aluminum (TiA1), tantalum aluminum (TaA1), other suitable work function materials, or a combination thereof. In some embodiments, work function metal layers 146A and 146B may be made of a same material, which will be beneficial for achieving substantially same threshold voltage for different transistors, and will further reduce manufacturing complexity. In other embodiments, the work function metal layers 146A and 146B may be made of different work function materials.

After the work function metal layers 146A and 146B are formed, a deposition process is performed to form the filling metals 148A and 148B. For example, a filling conductive material is formed over the substrate 100 and filling the space outside the work function metal layers 146A and 146B. In some embodiments, the deposition process may include physical vapor deposition (PVD), chemical vapor deposition (CVD),

atomic layer deposition (ALD), or the like. In some embodiments, the filling metals 148A and 148B may include titanium nitride (TiN). In other embodiments, the filling metals 148A and 148B may include tungsten (W), aluminum (Al), copper (Cu), or another suitable conductive material(s). In some embodiments, the thickness of the work function metal layers 146A and 146B is in a range from about 20 nm to about 40 nm (e.g., 30 nm), and the thickness of the filling metals 148A and 148B is in a range from about 50 nm to about 70 nm (e.g., 60 nm).

A patterned mask MA3 is then formed over the work function metal layers 146A and 146B. Then, an etching process is performed to remove portions of the interfacial layers 142A and 142B, the high-k dielectric layers 144A and 144B, the work function metal layers 146A and 146B, and the filling metals 148A and 148B exposed through the patterned mask MA3, and the resulting gate stack 140 is shown in FIGS. 8A and 8B. In some embodiments, the patterned mask MA3 may be photoresist.

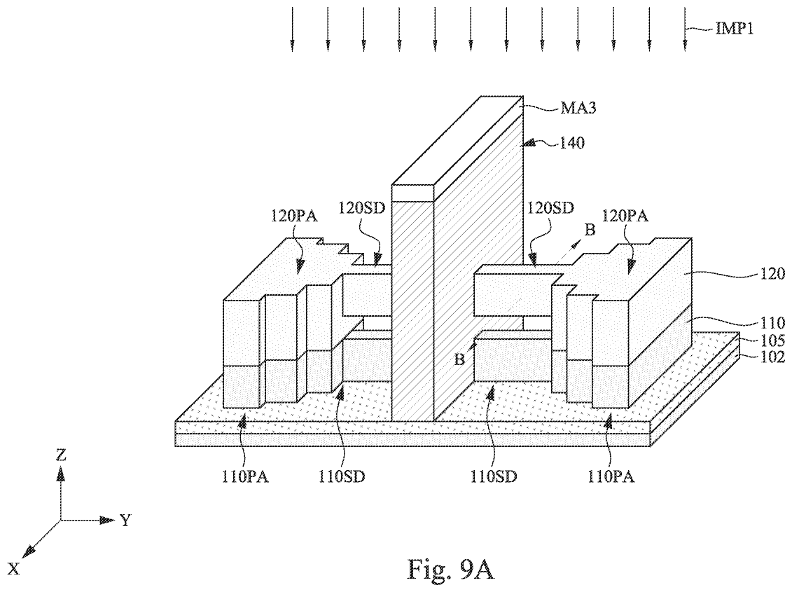

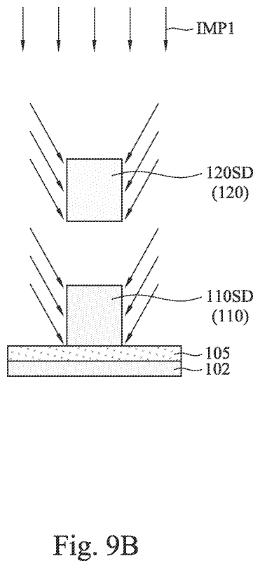

Reference is made to FIGS. 9A and 9B, in which FIG. 9A is a schematic view of a semiconductor device, and FIG. 9B is a cross-sectional view along line B-B of FIG. 9A. After the gate stack 140 is formed, a first implantation process IMP1 is performed to dope the source/drain regions 110SD of the semiconductor layer 110 and the source/drain regions 120SD of the semiconductor layer 120. It is noted that, during the first implantation process IMP1, the pad regions 110PA of the semiconductor layer 110 and the pad regions 120PA of the semiconductor layer 120 may also be doped, and thus relevant details will not be repeated for brevity. During the first implantation process IMP1, the mask MA3 may act as a protective layer to prevent the gate stack 140 from damage.

In some embodiments, the implants of the first implantation process IMP1 may be n-type dopants, such as phosphorus (P), arsenic (As), or antimony (Sb), or the like. That is, after the first implantation process IMP1 is complete, the source/drain regions 110SD of the semiconductor layer 110 and the source/drain regions 120SD of the semiconductor layer 120 are both n-type doped regions. In some embodiments, the first

implantation process IMP1 is performed with 9 keV to about 12 keV (e.g., 10 keV), and with a dose of about 1×10¹⁵ cm⁻² to about 2×10¹⁵ cm⁻² (e.g., 1×10¹⁵ cm⁻²).

In some embodiments, the first implantation process IMP1 is performed by generating implants toward the substrate 100 with a non-zero tilted angle 0. Here, the “tilted angle 0” may be the angle between the incident direction of the implants and the normal line of the top surface of the substrate 100 (or the normal lines of the top surfaces of the semiconductor layers 110 and 120). In practice, during the first implantation process IMP1, the incident direction of the implants may be fixed, and the substrate 100 can be rotated by the angle 0, such that the incident direction of the implants is tilted with respect to the substrate 100. The first implantation process IMP1 is performed with tilted angle 0 may be beneficial to form doped regions in the source/drain regions 110SD of the semiconductor layer 110 at a lower level. If the first implantation process IMP1 is performed without tilting the incident direction (e.g., tilted angle 0 is 0°), the incident direction may be perpendicular to the top surface of the substrate 100 (or the top surfaces of the semiconductor layers 110 and 120). In such condition, the semiconductor layer 120 may block the implants, and the implants may not be able to reach the source/drain regions 110SD of the semiconductor layer 110. In some embodiments, the tilted angle 0 is in a range from about 5° to about 30°, such as 12°. If the tilted angle 0 is too small (e.g., much smaller than 5°), most of the implants may be blocked by the semiconductor layer 120. If the tilted angle 0 is too large (e.g., much greater than 30°), the incident direction may be too flat and the implants may be blocked by other structures (not shown) over the substrate 100.

In greater detail, the first implantation process IMP1 may include a first step and a second step. The first step includes generating the implants toward one side of the source/drain regions 110SD of the semiconductor layer 110 and one side of the source/drain regions 120SD of the semiconductor layer 120. After the first step is complete, substrate 100 (including the structures formed over the substrate 100) is twisted by about 180° with respect to the incident direction of the implants. Alternatively, the second step is then performed by generating the implants toward another side of the source/drain regions 110SD of the semiconductor layer 110 and

another side of the source/drain regions 120SD of the semiconductor layer 120. Accordingly, the source/drain regions 110SD of the semiconductor layer 110 and the source/drain regions 120SD of the semiconductor layer 120 may be doped from opposite sides to obtain a more uniform dopant concentration.

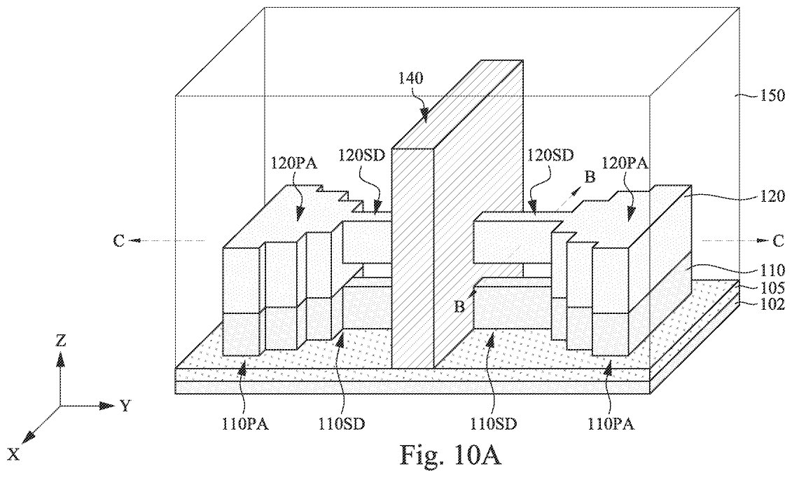

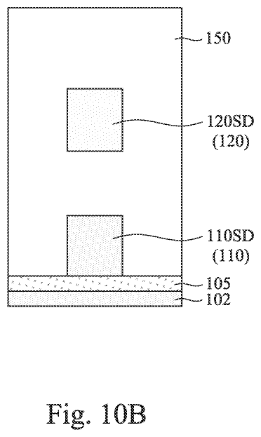

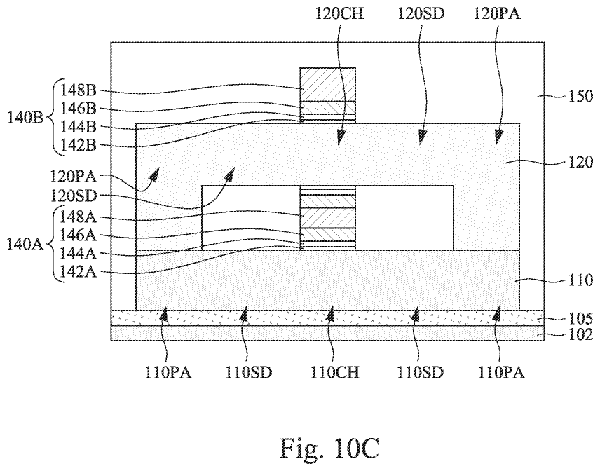

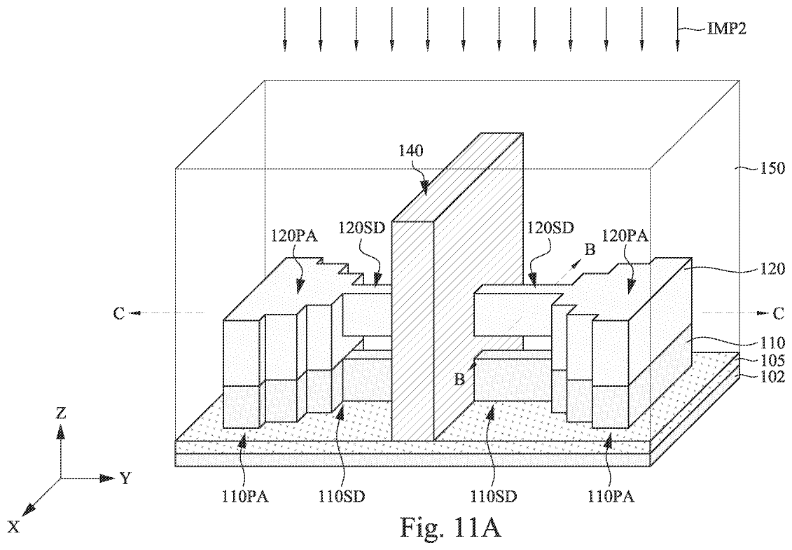

Reference is made to FIGS. 10A, 10B, and 10C, in which FIG. 10A is a schematic view of a semiconductor device, and FIG. 10B is a cross-sectional view along line B-B of FIG. 10A, and FIG. 10C is a cross-sectional view along line C-C of FIG. 10A. After the first implantation process IMP1 is complete, the mask MA3 is removed from the top surface of the gate stack 140. Afterwards, a dielectric layer 150 is formed over the substrate 100 and covering the gate stack 140 and the semiconductor layers 110 and 120. The dielectric layer 150 has a portion filling the space vertically between the semiconductor layers 110 and 120. This portion can act as a supporting structure of the semiconductor layer 120 to prevent the semiconductor layer 120 from collapse during the following processes.

In some embodiments, the dielectric layer 150 may include oxide, such as aluminum oxide (Al2O3). In other embodiments, the dielectric layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. In some embodiments, the deposition process may be a conformal deposition process, such as chemical vapor deposition (CVD), atomic layer deposition (ALD), or the like. In some embodiments, the thickness of the dielectric layer 150 is in a range from about 18 nm to 22 nm, such as 20 nm.

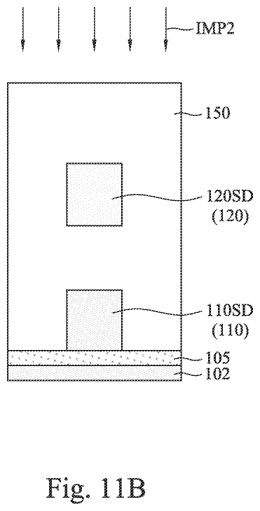

Reference is made to FIGS. 11A and 11B, in which FIG. 11A is a schematic view of a semiconductor device, and FIG. 11B is a cross-sectional view along line B-B of FIG. 11A. After the dielectric layer 150 is formed, a second implantation process IMP2 is performed to dope the source/drain regions 120SD of the semiconductor layer 120. During the second implantation process IMP2, the pad regions 120PA of the semiconductor layer 120 may also be doped, and thus relevant details will not be

repeated for brevity. During the second implantation process IMP2, the dielectric layer 150 may act as a protective layer to prevent surface damage on the source/drain regions 120SD of the semiconductor layer 120.

In some embodiments, the implants of the second implantation process IMP2 may be p-type dopants, such as boron (B), gallium (Ga), indium (In), aluminium (Al), or the like. In some embodiments, the second implantation process IMP2 is performed with 9 keV to about 12 keV (e.g., 10 keV), and with a dose of about 1×10¹⁵ cm⁻² to about 2×10¹⁵ cm⁻² (e.g., 1×10¹⁵ cm⁻²).

In some embodiments, the second implantation process IMP2 is performed by generating implants vertically toward the substrate 100. That is, the second implantation process IMP2 is performed without tilted angle (e.g., tilted angle 0 is 0°). Stated another way, the incident direction of the implants may be perpendicular to the top surface of the substrate 100 (or the top surface of the semiconductor layer 120). Therefore, the second semiconductor layer 120 may undergo the second implantation process IMP2, and may also block the implants of the second implantation process IMP2 from reaching the source/drain regions 110SD of the semiconductor layer 110. As a result, the source/drain regions 110SD of the semiconductor layer 110 may not undergo the second implantation process IMP2, and thus the source/drain regions 110SD of the semiconductor layer 110 may be free of p-type dopants used in the second implantation process IMP2.

Based on the above discussion, it can be seen that the source/drain regions 120SD of the semiconductor layer 120 may undergo the first implantation process IMP1 (with n-type implants) and the second implantation process IMP2 (with p-type implants). As a result, the n-type implants and p-type implants may be detectable from the source/drain regions 120SD of the semiconductor layer 120. For example, when phosphorus (P) is used in the first implantation process IMP1 and boron (B) is used in the second implantation process IMP2, phosphorus (P) and boron (B) may be detectable from the source/drain regions 120SD of the semiconductor layer 120, while only phosphorus (P) can be detectable from the source/drain regions 110SD of the

semiconductor layer 110. Although the source/drain regions 120SD of the semiconductor layer 120 include both n-type dopants and p-type dopants, the source/drain regions 120SD of the semiconductor layer 120 may present p-type conductivity type as measured by Hall-Effect measurement, which will be discussed later.

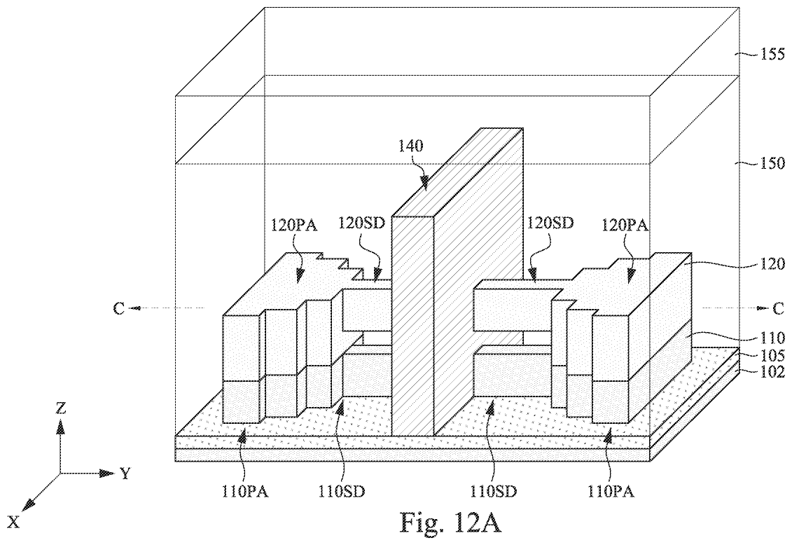

Reference is made to FIGS. 12A and 12B, in which FIG. 12A is a schematic view of a semiconductor device, and FIG. 12B is a cross-sectional view along line C-C of FIG. 12A. After the second implantation process IMP2 is complete, a dielectric layer 155 is formed over the dielectric layer 150. In some embodiments, the dielectric layer 155 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. In some embodiments, the deposition process may be a conformal deposition process, such as chemical vapor deposition (CVD), atomic layer deposition (ALD), or the like. In some embodiments, the thickness of the dielectric layer 155 is in a range from about 18 nm to 22 nm, such as 20 nm. The dielectric layers 150 and 155 may be made of different dielectric materials, while the present disclosure is not limited thereto. In some embodiments, the dielectric layer 150 may include aluminum oxide (A1₂0₃) and the dielectric layer 155 may include silicon oxide (SiO₂).

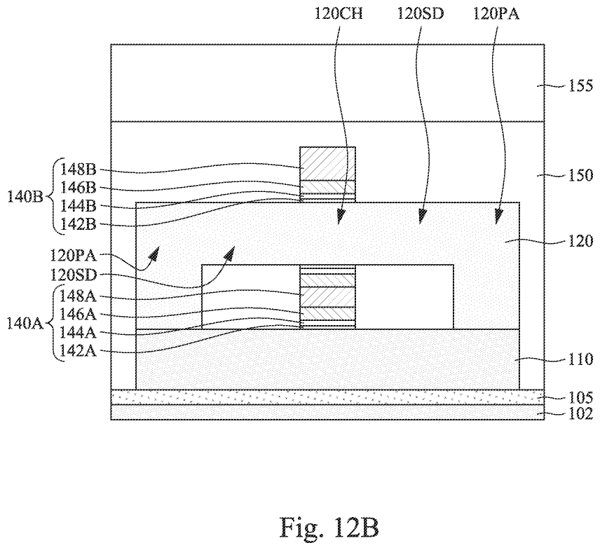

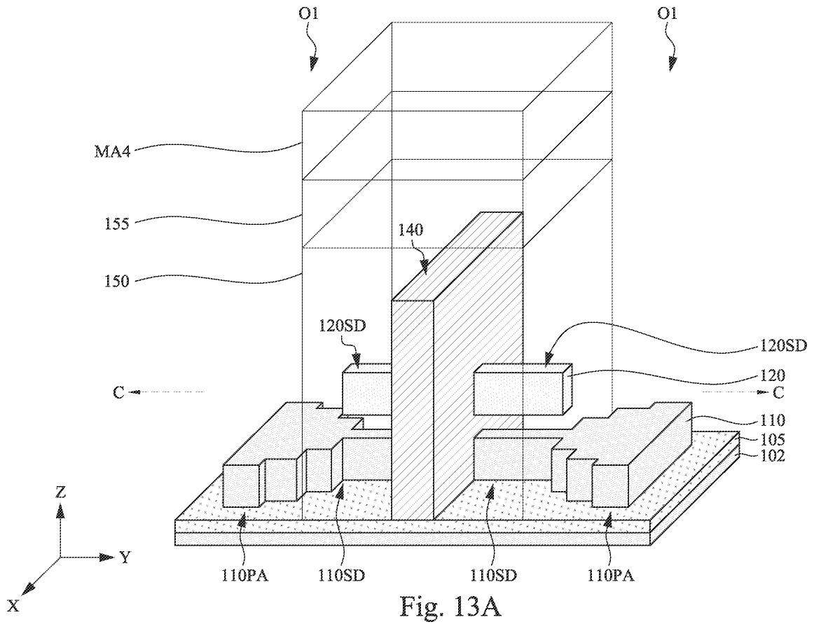

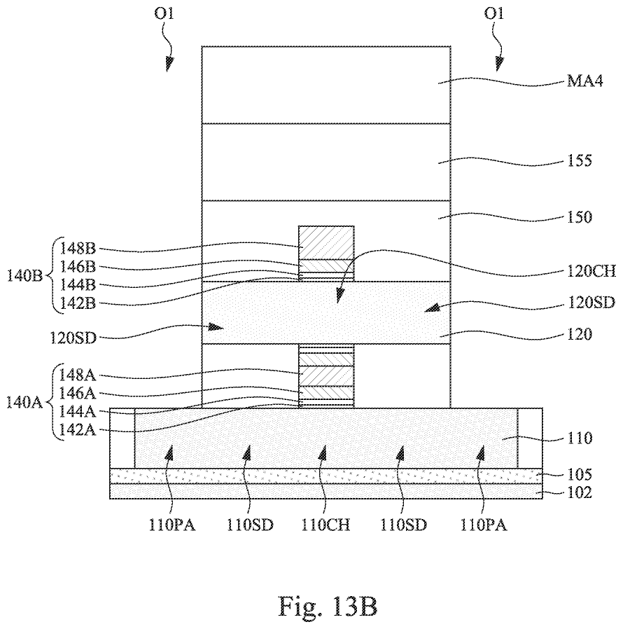

Reference is made to FIGS. 13A and 13B, in which FIG. 13A is a schematic view of a semiconductor device, and FIG. 13B is a cross-sectional view along line C-C of FIG. I3A. A mask MA4 is formed over the dielectric layer 155, and the mask MA4 may be patterned to form openings 01. In some embodiments, the openings 01 may vertically overlap the pad regions 120PA of the semiconductor layer 120, respectively. Afterwards, an etching process is performed, through the openings 01 of the mask MA4, to remove portions of the dielectric layer 155, portions of the dielectric layer 150, and the pad regions 120PA of the semiconductor layer 120. The etching process may be stopped once the pad regions 120PA of the semiconductor layer 120 are removed. Accordingly, the pad regions 110PA of the semiconductor layer 110 may be exposed through the openings 01.

In some embodiments, the dielectric layer 155 may act as an adhesive layer between the dielectric layer 150 and the mask MA4. If the dielectric layer 155 is absent, the mask MA4 may be in contact with the dielectric layer 150. However, experiment results show that the mask MA4 may be easily peeled away from the dielectric layer 150, and will deteriorate the device quality. Thus, the dielectric layer 155 may be beneficial to improve the process quality.

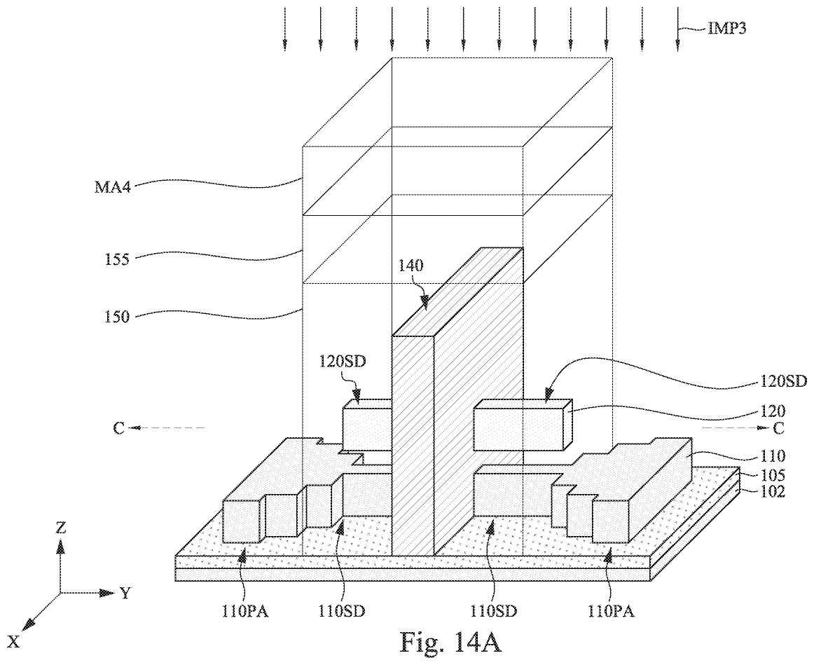

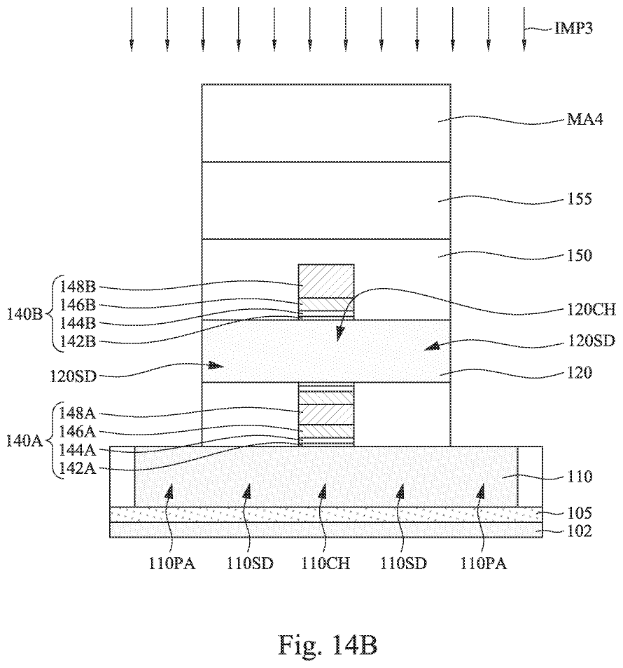

Reference is made to FIGS. 14A and 14B, in which FIG. 14A is a schematic view of a semiconductor device, and FIG. 14B is a cross-sectional view along line C-C of FIG. 14A. A third implantation process IMP3 is performed to dope the pad regions 110PA of the semiconductor layer 110 through the openings 01 of the dielectric layers 150 and 155. In some embodiments, the implants of the third implantation process IMP3 may be n-type dopants, such as phosphorus (P), arsenic (As), or antimony (Sb), or the like. That is, after the third implantation process IMP3 is complete, the pad regions 110PA of the semiconductor layer 110 are n-type doped regions. In some embodiments, the third implantation process IMP3 is performed with power of 9 keV to about 12 keV (e.g., 10 keV), and with a dose of about 1×10¹⁵ cm⁻² to about 2×10¹⁵ cm⁻² (e.g., 1×10¹⁵ cm⁻²).

In some embodiments, the third implantation process IMP3 is performed by generating implants vertically toward the substrate 100. That is, the third implantation process IMP3 is performed without tilted angle (e.g., tilted angle 0 is 0°). Stated another way, the incident direction of the implants may be perpendicular to the top surface of the substrate 100 (or the top surface of the semiconductor layer 110).

As mentioned above, during the first implantation process IMP1 as discussed in FIGS. 9A and 9B, the pad regions 110PA of the semiconductor layer 110 may also be doped with n-type dopants through the first implantation process IMP1. However, because the area of the pad regions 110PA of the semiconductor layer 110 is too large, only the edge regions of the pad regions 110PA of the semiconductor layer 110 may be doped. Accordingly, the third implantation process IMP3 may be further performed to dope the pad regions 110PA of the semiconductor layer 110 from the top surfaces of the

pad regions 110PA of the semiconductor layer 110, such that the entire pad regions 110PA of the semiconductor layer 110 may be doped with desired implants.

After the third implantation process IMPS is complete, an annealing process is performed to activate the implants in the source/drain regions 110SD of the semiconductor layer 110 and the implants in the source/drain regions 120SD of the semiconductor layer 120. In some embodiments, the annealing process may be a low temperature microwave annealing (MWA) process. The annealing process may be performed under a temperature in a range from about 400° C. to about 550° C., such as 450° C., a power in a range from about 1600 W to about 1700 W, such as 1650 W, and a duration in a range from about 80 s to about 120 s, such as 100 s. In some embodiments, if the temperature is too high (e.g., much higher than 550° C.), the semiconductor layer 120 (e.g., Ge) may be damaged. If the temperature is too low (e.g., much lower than 400° C.), the temperature may not be able to activate the source/drain regions. The low temperature MWA process may be beneficial to improve SS ratio, increase Ion/Ioff ratio, and may suppress implants from over-diffusion.

After the activation process (or the annealing process) is complete, the channel region 110CH and the source/drain regions 110SD of the semiconductor layer 110 and the gate structure 140A may collectively serve as a first transistor. On the other hand, the channel region 120CH and the source/drain regions 120SD of the semiconductor layer 120 and the gate structure 140B may collectively serve as a second transistor stacked above the first transistor.

As mentioned above, the source/drain regions 120SD of the semiconductor layer 120 include both n-type dopants and p-type dopants. As a result, after the activation process (or the annealing process) is complete, a Hall-Effect measurement is performed to the source/drain regions 120SD of the semiconductor layer 120 to determine the conductivity type of the source/drain regions 120SD. The Hall-Effect measurement may also be performed to a sample having larger scale, in which the sample may also undergo the implantation processes and the activation process as discussed above. The Hall effect is a phenomenon that a electromotive force is

generated in the direction transverse to both electric current and a magnetic field as the magnetic field vertical to the electric current is applied, and is used to mainly identify a carrier density, mobility, and a conductivity type of a semiconductor. In some embodiments where the phosphorus (P) is used in the first implantation process IMP] with dose of about 1×10¹⁵ cm⁻² and power of about 10 keV, and boron (B) is used in the second implantation process IMP2 with dose of about 1×15 cm² and power of about 10 keV, the measurement result shows that the source/drain regions 120SD presents p-type conductivity with carrier (e.g., hole) concentration about 1×10¹⁹cm⁻³. On the other hand, the source/drain regions 110SD of the semiconductor layer 110 will present n-type conductivity because the source/drain regions 110SD only include n-type dopants. As a result, the source/drain regions 120SD of the semiconductor layer 120 can be referred to as a p-type doped region, and the source/drain regions 110SD of the semiconductor layer 110 can be referred to as a n-type doped region. Here, the “p-type doped region” may be referred to as a region by using hole as carrier, and the “n-type doped region” may be referred to as a region by using electron as carrier. Accordingly, the first transistor at the lower level may be an n-type device, and the second transistor at the higher level may be a p-type device. In other embodiments, the source/drain regions 120SD may also present p-type conductivity if the annealing process is omitted.

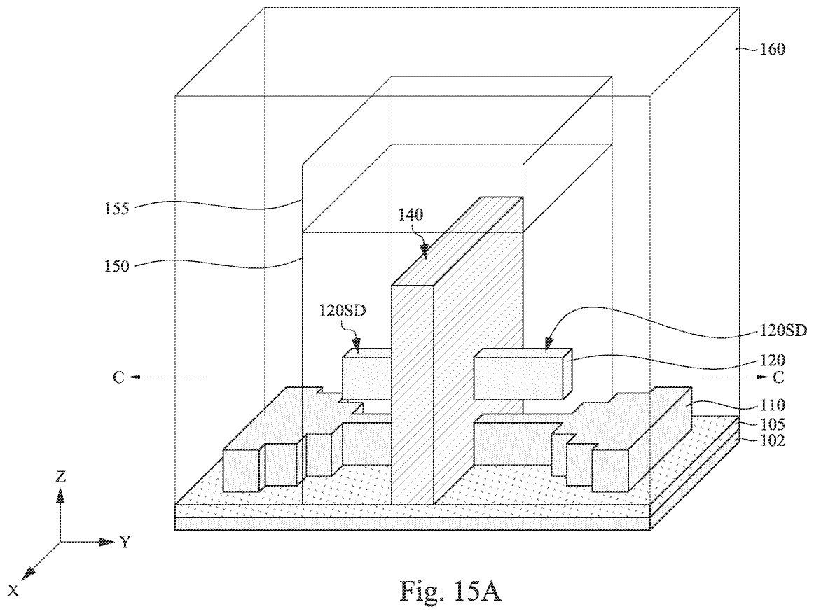

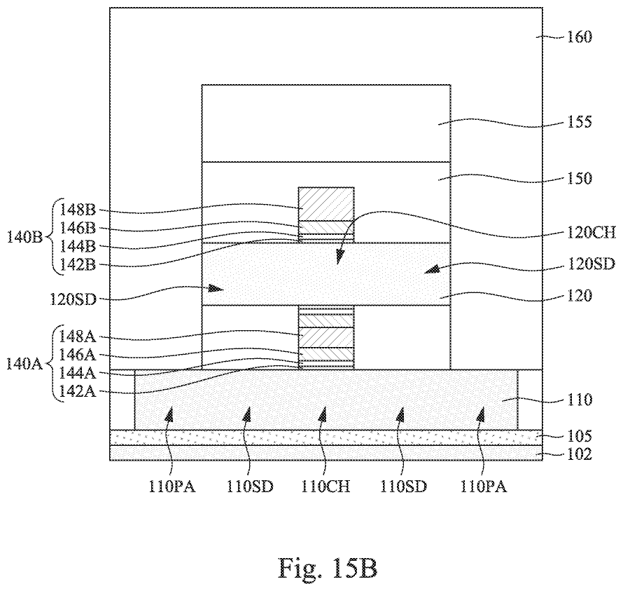

Reference is made to FIGS. 15A and 15B, in which FIG. 15A is a schematic view of a semiconductor device, and FIG. 15B is a cross-sectional view along line C-C of FIG. 15A. The mask MA4 is removed after the third implantation process IMP3 is complete. A dielectric layer 160 is formed over the dielectric layer 155 and filling the openings 01 of the dielectric layers 150 and 155. In some embodiments, the dielectric layer 160 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. In some embodiments, the deposition process may be a conformal deposition process, such as chemical vapor deposition (CVD), atomic layer deposition (ALD), or the like.

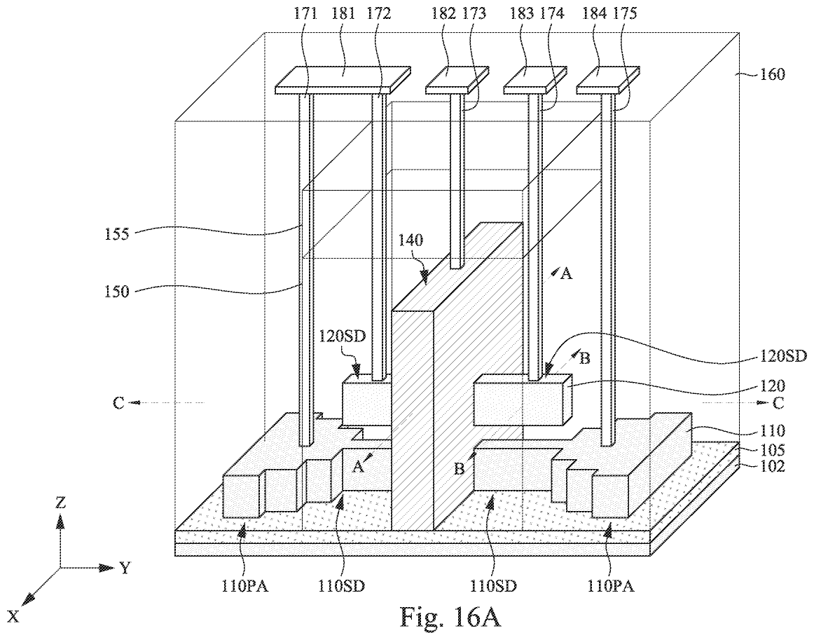

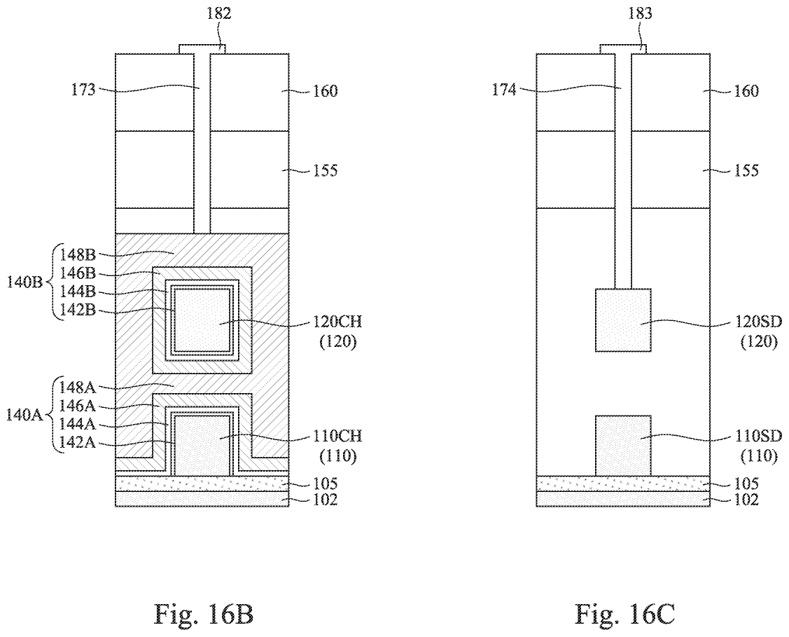

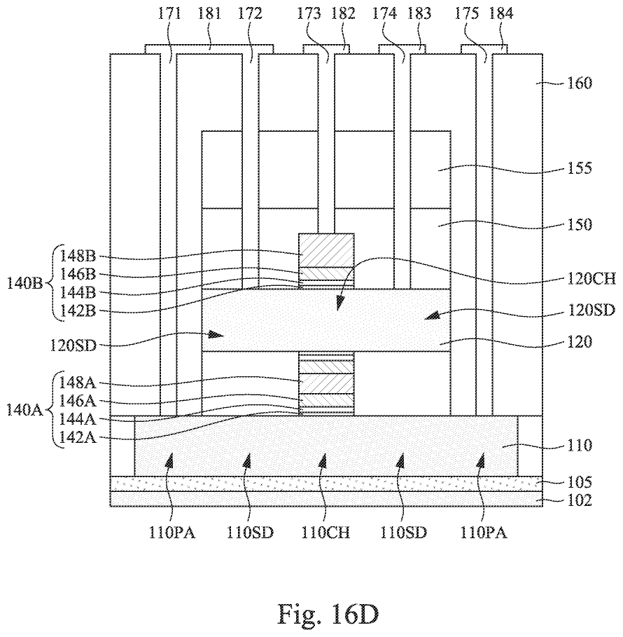

Reference is made to FIGS. 16A, 16B, 16C, and 16D, in which FIG. 16A is a schematic view of a semiconductor device, FIG. 16B is a cross-sectional view along line

A-A of FIG. 16A, FIG. 16C is a cross-sectional view along line B-B of FIG. 16A, and FIG. 16D is a cross-sectional view along line C-C of FIG. 16A. Conductive vias 171, 172, 173, 174, and 175 are formed in the dielectric layers 150, 155, and 160. In greater detail, the conductive via 171 is in contact with one pad region 110PA of the semiconductor layer 110. The conductive via 172 is in contact with one source/drain region 120SD of the semiconductor layer 120. The conductive via 173 is in contact with the gate stack 140. The conductive via 174 is in contact with another one source/drain region 120SD of the semiconductor layer 120. The conductive via 175 is in contact with another one pad region 110PA of the semiconductor layer 110. In some embodiments, the source/drain regions 110SD of the semiconductor layer 110 may be electrically connected with the respective conductive vias 171 and 175 through the pad regions 110PA of the semiconductor layer 110.

The conductive vias 171, 172, 173, 174, and 175 may be formed by, for example, forming a patterned mask (not shown) over the dielectric layer 160, in which the patterned mask may include several openings correspond to the positions of the conductive vias 171, 172, 173, 174, and 175. An etching process is performed to remove portions of the dielectric layers 150, 155, and 160 through the openings of the patterned mask, so as to form openings in the dielectric layers 150, 155, and 160 that expose the pad region 110PA of the semiconductor layer 110, the source/drain regions 120SD of the semiconductor layer 120, and the gate stack 140. The patterned mask is then removed, and a conductive material is deposited in the openings of the dielectric layers 150, 155, and 160. A planarization process, such as CMP, may be performed to remove excess conductive material outside the openings of the dielectric layers 150, 155, and 160, and the portions of the conductive material remain in the openings may serve as the conductive vias 171, 172, 173, 174, and 175. The conductive vias 171, 172, 173, 174, and 175 may include a conductive material, such tungsten (W), copper (Cu), aluminum (Al), ruthenium (Ru), cobalt (Co), molybdenum (Mo), nickel (Ni), or other suitable conductive material.

Conductive pads 181, 182, 183, and 184 are formed over the dielectric layer 160. In greater detail, the conductive pad 181 may be in contact with the conductive vias 171

and 172. The conductive pad 182 may be in contact with the conductive via 173. The conductive pad 1832 may be in contact with the conductive via 174. The conductive pad 184 may be in contact with the conductive via 175. The conductive pads 181, 182, 183, and 184 may be formed by, for example, depositing a conductive layer over the dielectric layer 160, and then patterning the conductive layer according to a predetermined pattern. The conductive pads 181, 182, 183, and 184 may include a conductive material, such tungsten (W), copper (Cu), aluminum (Al), ruthenium (Ru), cobalt (Co), molybdenum (Mo), nickel (Ni), or other suitable conductive material.

In some embodiments, the first and second transistors, the conductive vias 171, 172, 173, 174, and 175, and the conductive pads 181, 182, 183, and 184 may collectively serve as an inverter. For example, the conductive pad 182 may serve as the input terminal V_{IN} of the inverter, the conductive pad 183 may serve as the power supply terminal V_{DD} of the second transistor, and the conductive pad 184 may serve as the power supply terminal V_{SS} of the first transistor, and the conductive pad 181 may serve as the output terminal V_{DDT} of the inverter. In some embodiments, the power supply terminal VDD o is connected with a positive voltage, and the power supply terminal Vss is grounded.

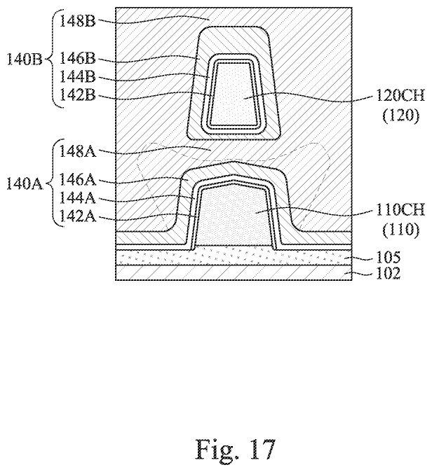

FIG. 17 is a cross-sectional view of a semiconductor device in accordance with some embodiments of the present disclosure. FIG. 17 is similar to the cross-sectional view of FIG. 16B. The structure of FIG. 17 is different from the structure of FIG. 16B, in that after the etching processes as discussed in FIGS. 3 to 6, the semiconductor layers 110 and 120 may include tapered cross-sectional profile. For example, with respect to the semiconductor layer 110, the lateral width of the semiconductor layer 110 may increase from the top of the semiconductor layer 110 toward the bottom of the semiconductor layer 110. In some embodiments, the bottom surface of the semiconductor layer 110 is about 42 nm, and the top surface of the semiconductor layer 110 is about 33 nm, and the height of the semiconductor layer 110 is about 33 nm. Similarly, the lateral width of the semiconductor layer 120 may increase from the top of the semiconductor layer 120 toward the bottom of the semiconductor layer 120. In some embodiments, the bottom surface of the semiconductor layer 120 is about 32 nm,

and the top surface of the semiconductor layer 120 is about 19 nm, and the height of the semiconductor layer 120 is about 42 nm.

With respect to the work function metal layers 146A and 146B, the work function metal layers 146A and I46B may be deposited using a directional deposition process, such as physical vapor deposition (PVD). The directional deposition may result in the material of the work function metal layer 146B having different deposition rates at different surfaces of the semiconductor layer 120. For example, with respect to the work function metal layer 146B, the work function metal layer 146B may include a first portion over the top surface of the semiconductor layer 120, second portions on opposite sidewalls of the semiconductor layer 120, and a third portion at the bottom surface of the semiconductor layer 120, in which the first portion is thicker than the second portion, and the second portion is thicker than the third portion. In some embodiments, the thickness of the second portion is about 17 nm. On the other hand, the work function metal layer 146A may include substantially uniform thickness.

With respect to the filling metals 148A and 148B. The filling metals 148A and 148B may be different portions of a single piece material. However, during the deposition of the filling metals 148A and 148B, an observable interface (see the dash line) may present in the single piece material of the filling metals 148A and 148B.

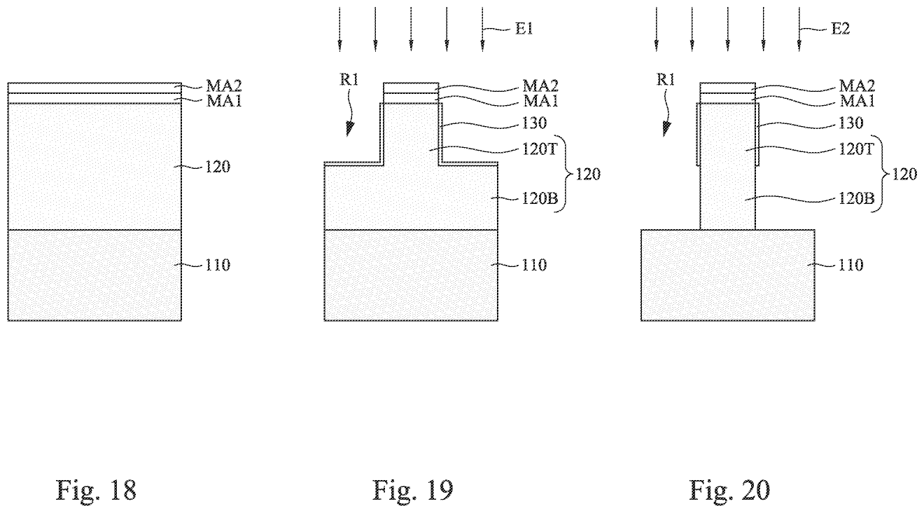

FIGS. 18 to 24D illustrate a method in various stages of forming a semiconductor device in accordance with some embodiments of the present disclosure. It is noted that some elements of FIGS. 18 to 24D have been discussed above with respect to FIGS. 1 to 16D, such elements are labeled and relevant details will not be repeated for brevity.

Reference is made to FIG. 18. FIG. 18 is similar to FIG. 2B, the difference between FIG. 18 and FIG. 2B is that there are no dielectric layer 105 and the semiconductor layer 102 in the structure of FIG. 18. That is, the semiconductor layer 110 may serve as the substrate.

Reference is made to FIG. 19. A first etching process El is performed to remove portions of the semiconductor layer 120 that are exposed through the masks MA1 and MA2, so as to form recesses RI in the semiconductor layer 120. As a result of the first etching process El, the etched semiconductor layer 120 may include a top portion 120T and a bottom portion 120B under the top portion 120T. As mentioned above with respect to FIG. 3, oxygen (0₂) is used in the first etching process El, and thus oxide layers 130 may be formed on the exposed surfaces of the semiconductor layer 120 as byproduct of the first etching process El.

Reference is made to FIG. 20. After the first etching process El is complete, a second etching process E2 is performed to remove horizontal portions of the oxide layers 130 to expose the bottom portion 120B of the semiconductor layer 120. Once the horizontal portions of the oxide layers 130 are removed, the second etching process E2 removes the exposed bottom portion 120B of the semiconductor layer 120 until the underlying semiconductor layer 110 is exposed.

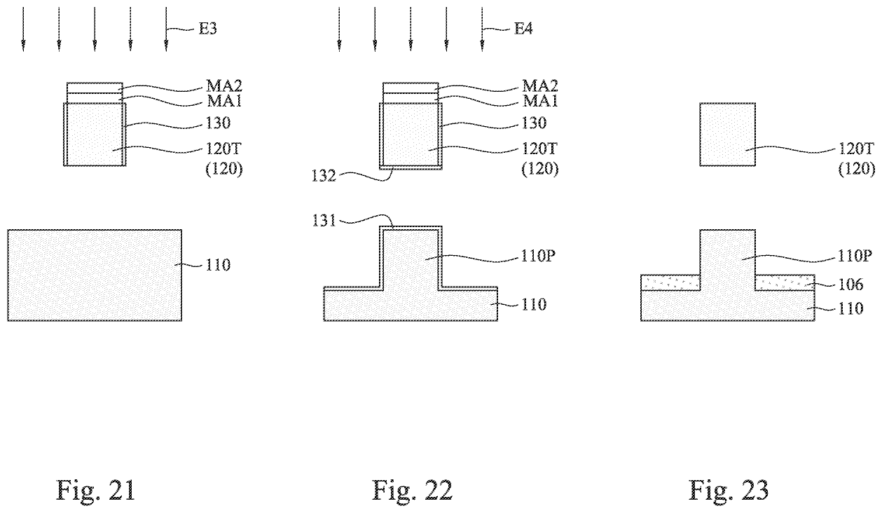

Reference is made to FIG. 21. After the second etching process E2 is complete, a third etching process E3 is performed to remove the bottom portion 120B of the semiconductor layer 120. As a result of the third etching process E3, the semiconductor layer 120 is vertically separated from the semiconductor layer 110.

Reference is made to FIG. 22. After the third etching process E3 is complete, a fourth etching process E4 is performed to remove portions of the semiconductor layer 110 exposed through the top portion 120T of the semiconductor layer 120 (or the masks MA1 and MA2), so as to form a protrusion portion 110P protrudes from the top surface of the semiconductor layer 110. In some embodiments, the protrusion portion 110P may also be referred to as a fin structure over the semiconductor layer 110.

As mentioned above with respect to FIG. 6, because oxygen (0₂) is used in the fourth etching process E4, oxide layers 131 and 132 may be formed respectively on the exposed surfaces of the semiconductor layer 110 and the semiconductor layer 120 as byproduct of the fourth etching process E4. In greater detail, the oxide layer 131 may

line the top surface of the semiconductor layer 110, and may also line the top surface and sidewalls of the protrusion portion 110P.

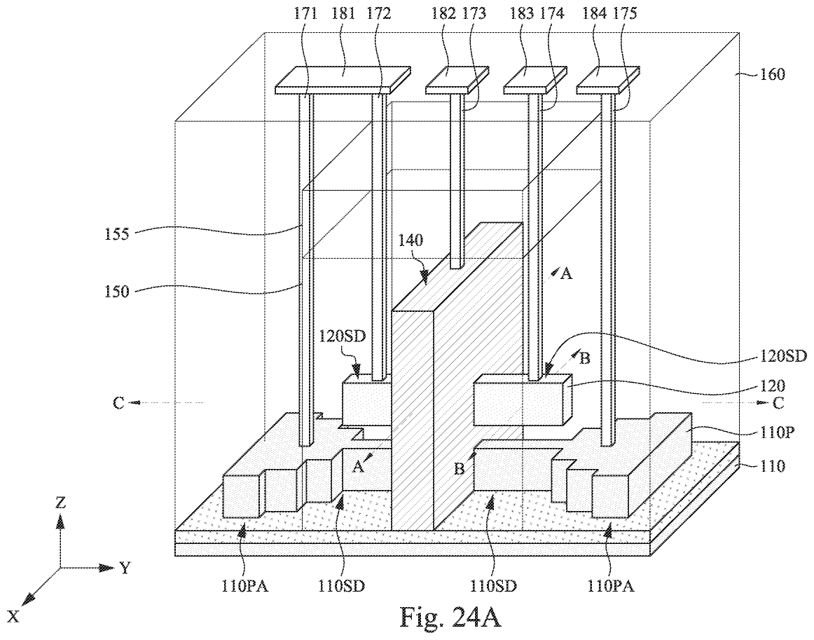

Reference is made to FIG. 23. After the etching processes are complete, the masks MA1 and MA2 are removed from the top surface of the semiconductor layer 120. Moreover, a pre-clean process is performed to remove the oxide layers 130, 131, and 132, such that surfaces of the semiconductor layers 110 and 120 are exposed, and the resulting structure is shown in FIG. 23.

Afterwards, isolation structure 106 is formed over the semiconductor layer 110 and laterally surrounds the protrusion portion 110P. The isolation structure 106 may be formed by, for example, depositing a dielectric material over the semiconductor layer 110, and then etching back the dielectric material to lower the top surface of the dielectric material to a desired position. In some embodiments, the top surface of the isolation structure 106 is lower than the top surface of the protrusion portion 110P. That is, the isolation structure 106 laterally surrounds the bottom portion of the protrusion portion 1IOP, while the upper portion of the protrusion portion 110P may protrudes from the top surface of the isolation structure 106. The isolation structure 106 may also be referred to as shallow trench isolation (STI) structure.

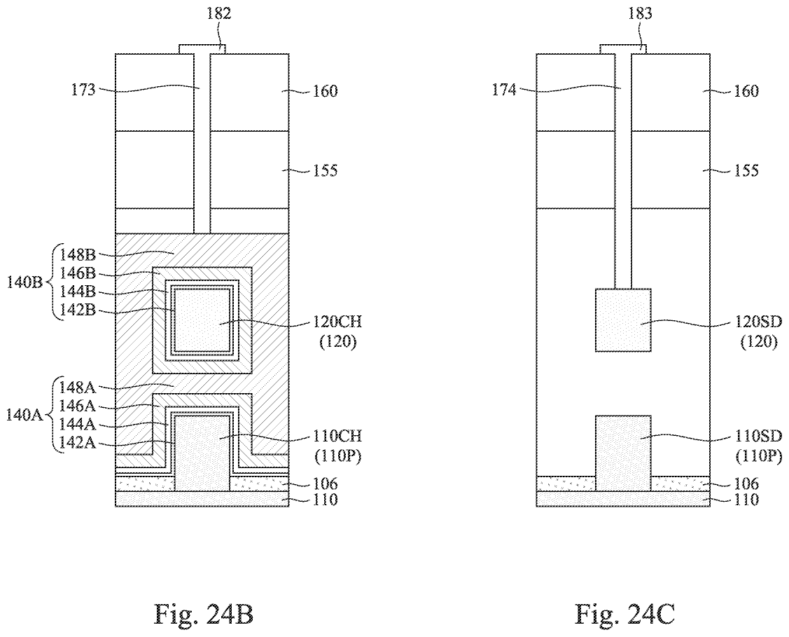

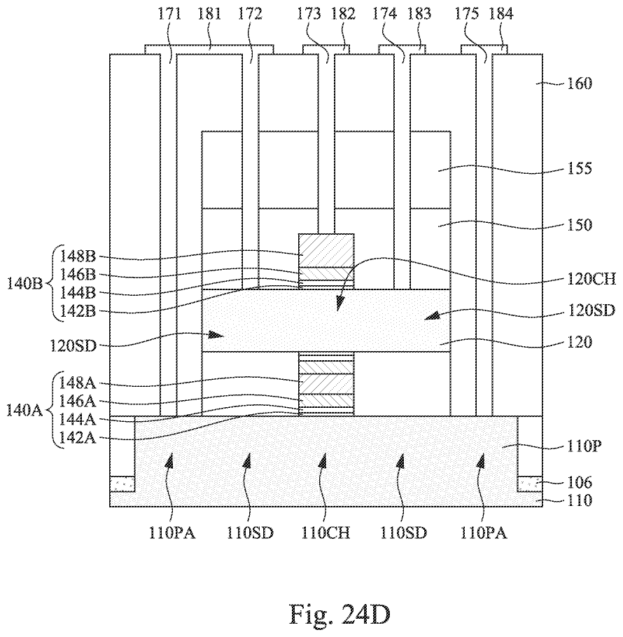

Reference is made to FIGS. 24A, 24B, 24C, and 24D, in which FIG. 24A is a schematic view of a semiconductor device, FIG. 24B is a cross-sectional view along line A-A of FIG. 24A, FIG. 24C is a cross-sectional view along line B-B of FIG. 24A, and FIG. 24D is a cross-sectional view along line C-C of FIG. 16A. The structure of FIG. 23 may undergo the processes as discussed in FIGS. 8A to 16D, and the resulting structure is shown in FIGS. 24A, 24B, 24C, and 24D. The structure of FIGS. 24A to 24D is different from the structure of FIGS. 16A to 16D, in that in the structure of FIGS. 16A to 16D, a dielectric layer 105 is disposed below the bottom surface of the semiconductor layer 110. On the other hand, in the structure of FIGS. 24A to 24D, the isolation structure 106 is disposed over the semiconductor layer 110 and laterally surrounds the protrusion portion 110P of the semiconductor layer 110.

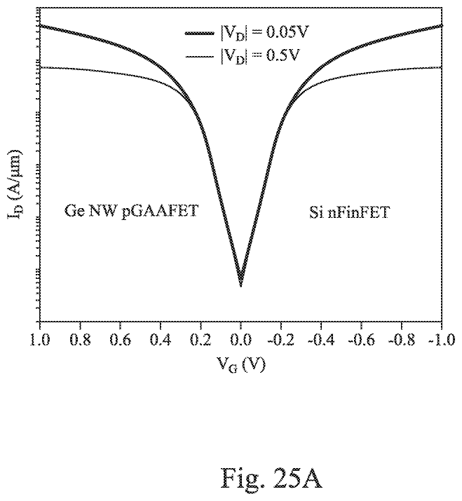

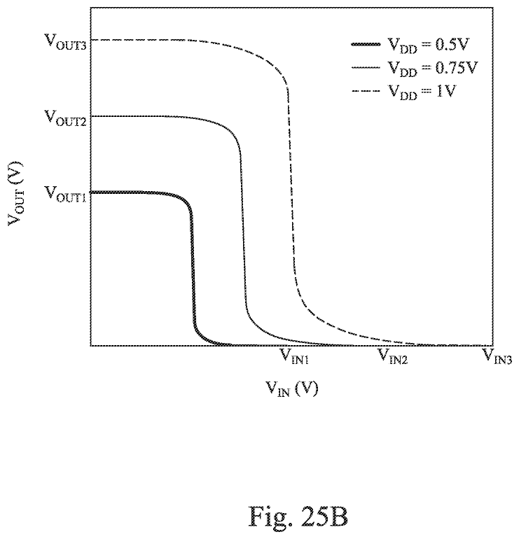

FIGS. 25A and 25B are simulation results of a semiconductor device in accordance with some embodiments of the present disclosure. In greater detail, FIGS. 25A and 25B are simulation results of the semiconductor device as discussed in FIGS. 16A to 16D.

FIG. 25A illustrates drain current (I_{D}) versus gate voltage (V_{G}) under different drain voltages (VD) of the semiconductor device as discussed in FIGS. 16A to 16D. It can be seen that, if the work function metal layers 146A and 146B are made of a same material, the drain current (I_{D}) versus gate voltage (V_{G}) shows symmetry in currents of the Si nFinFET (e.g., first transistor) and Ge NW pGAAFET (e.g., second transistor). Moreover, the threshold voltages of such devices are substantially the same.

FIG. 25B illustrates output voltage _{(VouT)} versus input voltage (V_{IN}) under different supply voltages (V_{GG}) of the semiconductor device as discussed in FIGS. 16A to 16D. It can be seen that, if the work function metal layers 146A and 146B are made of a same material, the output voltage (V_{ouT}) and the input voltage (V_{IN}) show symmetry property. For example, under the condition where the supply voltage (V_{GG}) is 0.5V, the output voltage _{(VouT)}^{is} Vow⁻i when the input voltage (V_{IN}) is OV, and the input voltage (VIN) is VINI when the output voltage (V_{ouT}) is 0. In some embodiments, VOUT1 is substantially equal to _{VINI,} such as about 0.5V. Under the condition where the supply voltage (V_{GG}) is 0.75V, the output voltage _{(VouT)}^{is} _{VOUT2} when the input voltage (VIN) is OV, and the input voltage (VIN) is VIN2 when the output voltage (VouT) is 0. In some embodiments, _{VouT2} is substantially equal to _{VIN2,} such as about 0.75V. Under the condition where the supply voltage (V_{GG}) is 1V, the output voltage (VouT) is Voun when the input voltage (V_{IN}) is OV, and the input voltage (V_{IN}) is V_{IN3} when the output voltage (Vou_{T}) is 0. In some embodiments, \Toon is substantially equal to VIN3, such as about 1V.

According to the aforementioned embodiments, it can be seen that the present disclosure offers advantages in fabricating integrated circuits. It is understood,

however, that other' embodiments may offer additional advantages, and not all advantages are necessarily disclosed herein, and that no particular advantage is required
for all embodiments. Embodiments of the present disclosure provide a method for forming a CFET device. The method includes forming a second semiconductor layer directly over a first semiconductor layer, and using a four-step etching process to separate the second semiconductor layer and the first semiconductor layer. The method further include performing a first implantation process with tilted angle to successfully dope the first semiconductor layer at a lower level, followed by a second implantation process without tilted angle to dope the second semiconductor layer at a higher level. The method also includes forming work function metal layers of the first and second semiconductor layers with a same material, and may be possible for achieving substantially same threshold voltage for different transistors, and will further reduce manufacturing complexity.

In some embodiments of the present disclosure, a method includes forming a second semiconductor layer over a first semiconductor layer; performing a first etching process to form a recess in the second semiconductor layer, such that the second semiconductor layer includes a bottom portion and a top portion over the bottom portion, wherein the first etching process results in forming first dielectric layers on opposite sidewalls of the top portion; performing a second etching process to narrow the bottom portion of the second semiconductor layer; performing a third etching process to remove the bottom portion of the second semiconductor layer; performing a fourth etching process to narrow the first semiconductor layer; and forming a first gate structure over the first semiconductor layer and a second gate structure over the second semiconductor layer, respectively.

In some embodiments, wherein the first dielectric layers are further formed on top surfaces of the bottom portion of the second semiconductor layer during the first etching process, and the second etching process is performed such that portions of the first dielectric layers on the top surfaces of the bottom portion of the second semiconductor layer are removed, while portions of the first dielectric layers on the opposite sidewalls of the top portion of the second semiconductor layer remain after the second etching process is complete.

In some embodiments, the method further includes removing the first dielectric layers prior to forming the first gate structure and the second gate structure.

In some embodiments, the fourth etching process results in forming a second dielectric layer over exposed surfaces of the first semiconductor layer and forming a third dielectric layer over a bottom surface of the top portion of the second semiconductor layer, and removing the first dielectric layers further comprise removing the second and third dielectric layers.

In some embodiments, the second semiconductor layer is formed in contact with first semiconductor layer, and the first and second semiconductor layers are made of different semiconductor materials.

In some embodiments, the method further includes forming a mask over the second semiconductor layer prior to performing the first etching process; and removing the mask after the fourth etching process is complete.

In some embodiments, the first dielectric layers are an oxide of a material of the second semiconductor material.

In some embodiments, the first etching process comprises using chlorine and oxygen. The second first etching process comprises using chlorine. The third etching process comprises using chlorine and hydrogen bromide. The fourth etching process comprises using chlorine and oxygen.

In some embodiments of the present disclosure, a method includes forming a second semiconductor layer vertically above a first semiconductor layer over a substrate; forming a first gate structure over the first semiconductor layer and a second gate structure over the second semiconductor layer, respectively; performing a first implantation process to dope first source/drain regions of the first semiconductor layer and second source/drain regions of the second semiconductor layer with n-type dopants, wherein an incident direction of the n-type dopants is tilted by a non-zero angle with respect to a normal line of a top surface of the substrate; and performing a second implantation process to dope the second source/drain regions of the second

semiconductor layer with p-type dopants, wherein an incident direction of the p-type dopants is substantially perpendicular to the top surface of the substrate.

In some embodiments, the method further includes performing an annealing process to activate the first source/drain regions of the first semiconductor layer and the second source/drain regions of the second semiconductor layer, wherein after the annealing process is complete, the first source/drain regions of the first semiconductor layer presents n-type conductivity, and the second source/drain regions of the second semiconductor layer presents p-type conductivity.

In some embodiments, during the second implantation process, the second semiconductor layer blocks the p-type dopants from reaching the first semiconductor layer.

In some embodiments, forming a dielectric layer filling a space between the first semiconductor layer and the second semiconductor layer prior to performing the second implantation process.

In some embodiments, the dielectric layer covers a top surface of the second semiconductor layer.

In some embodiments, forming the second semiconductor layer vertically above the first semiconductor layer over the substrate comprises: forming a second semiconductor material over a first semiconductor material; etching the second semiconductor material such that the second semiconductor layer includes a bottom portion and a top portion over the bottom portion, the bottom portion being wider than the top portion, wherein the first etching process forms oxide layers on opposite sidewalls of the top portion; removing the bottom portion of the second semiconductor material; and etching the first semiconductor material.

In some embodiments, the first semiconductor layer is made of silicon, and the second semiconductor layer is made of germanium.

In some embodiments of the present disclosure, a first transistor over a substrate and a second transistor vertically above the first transistor. The first transistor includes a first semiconductor layer comprising a first channel region and first source/drain regions, and a first gate structure over the first channel region of the first semiconductor layer. The first semiconductor layer presents n-type conductivity. The second transistor includes a second semiconductor layer comprising a second channel region and second source/drain regions, and a second gate structure over the second channel region of the second semiconductor layer. The second semiconductor layer presents p-type conductivity, and n-type dopants of the first source/drain regions of the first semiconductor layer are detectable in the second source/drain regions of the second semiconductor layer.

In some embodiments, the first gate structure is in contact with three sides of the first channel region, and the second gate structure is in contact with four sides of the second channel region.

In some embodiments, the first semiconductor layer and the second semiconductor layer are made of different semiconductor materials.

In some embodiments, the first gate structure comprises a first interfacial layer in contact with the first channel region, a first high-k dielectric layer over the first interfacial layer, a first work function metal layer over the first high-k dielectric layer; and a first filling metal over the first work function metal layer. The second gate structure comprises a second interfacial layer in contact with the second channel region, a second high-k dielectric layer over the second interfacial layer, a second work function metal layer over the second high-k dielectric layer, a second filling metal over the second work function metal layer. The first interfacial layer and the second interfacial layer are made of different materials.

In some embodiments, the first work function metal layer and the second work function metal layer are made of a same material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a second semiconductor layer over a first semiconductor layer;
performing a first etching process to form a recess in the second semiconductor layer, such that the second semiconductor layer includes a bottom portion and a top portion over the bottom portion, wherein the first etching process results in forming first dielectric layers on opposite sidewalls of the top portion;
performing a second etching process to narrow the bottom portion of the second semiconductor layer;
performing a third etching process to remove the bottom portion of the second semiconductor layer;
performing a fourth etching process to narrow the first semiconductor layer; and
forming a first gate structure over the first semiconductor layer and a second gate structure over the second semiconductor layer, respectively.

2. The method of claim 1, wherein the first dielectric layers are further formed on top surfaces of the bottom portion of the second semiconductor layer during the first etching process, and the second etching process is performed such that portions of the first dielectric layers on the top surfaces of the bottom portion of the second semiconductor layer are removed, while portions of the first dielectric layers on the opposite sidewalls of the top portion of the second semiconductor layer remain after the second etching process is complete.

3. The method of claim 1, further comprising removing the first dielectric layers prior to forming the first gate structure and the second gate structure.

4. The method of claim 4, wherein the fourth etching process results in forming a second dielectric layer over exposed surfaces of the first semiconductor layer and forming a third dielectric layer over a bottom surface of the top portion of the second semiconductor layer, and removing the first dielectric layers further comprise removing the second and third dielectric layers.

5. The method of claim 1, wherein the second semiconductor layer is formed in contact with first semiconductor layer, and the first and second semiconductor layers are made of different semiconductor materials.

6. The method of claim 1, further comprising:
forming a mask over the second semiconductor layer prior to performing the first etching process; and
removing the mask after the fourth etching process is complete.

7. The method of claim 1, wherein the first dielectric layers are an oxide of a material of the second semiconductor material.

8. The method of claim 1, wherein:
the first etching process comprises using chlorine and oxygen,
the second first etching process comprises using chlorine,
the third etching process comprises using chlorine and hydrogen bromide, and
the fourth etching process comprises using chlorine and oxygen.

9. A method, comprising:
forming a second semiconductor layer vertically above a first semiconductor layer over a substrate;
forming a first gate structure over the first semiconductor layer and a second gate structure over the second semiconductor layer, respectively;
performing a first implantation process to dope first source/drain regions of the first semiconductor layer and second source/drain regions of the second semiconductor layer with n-type dopants, wherein an incident direction of the n-type dopants is tilted by a non-zero angle with respect to a normal line of a top surface of the substrate; and
performing a second implantation process to dope the second source/drain regions of the second semiconductor layer with p-type dopants, wherein an incident direction of the p-type dopants is substantially perpendicular to the top surface of the substrate.

10. The method of claim 9, further comprising performing an annealing process to activate the first source/drain regions of the first semiconductor layer and the second source/drain regions of the second semiconductor layer, wherein after the annealing process is complete, the first source/drain regions of the first semiconductor layer presents n-type conductivity, and the second source/drain regions of the second semiconductor layer presents p-type conductivity.

11. The method of claim 9, wherein during the second implantation process, the second semiconductor layer blocks the p-type dopants from reaching the first semiconductor layer.

12. The method of claim 9, further comprising forming a dielectric layer filling a space between the first semiconductor layer and the second semiconductor layer prior to performing the second implantation process.

13. The method of claim 12, wherein the dielectric layer covers a top surface of the second semiconductor layer.

14. The method of claim 9, wherein forming the second semiconductor layer vertically above the first semiconductor layer over the substrate comprises:
forming a second semiconductor material over a first semiconductor material;
etching the second semiconductor material such that the second semiconductor layer includes a bottom portion and a top portion over the bottom portion, the bottom portion being wider than the top portion, wherein the first etching process forms oxide layers on opposite sidewalls of the top portion;
removing the bottom portion of the second semiconductor material; and
etching the first semiconductor material.

15. The method of claim 9, wherein the first semiconductor layer is made of silicon, and the second semiconductor layer is made of germanium.

16. A semiconductor device, comprising:
a first transistor over a substrate and comprising:
a first semiconductor layer comprising a first channel region and first source/drain regions, wherein the first semiconductor layer presents n-type conductivity; and
a first gate structure over the first channel region of the first semiconductor layer; and
a second transistor vertically above the first transistor and comprising:
a second semiconductor layer comprising a second channel region and second source/drain regions, wherein the second semiconductor layer presents p-type conductivity, and wherein n-type dopants of the first source/drain regions of the first semiconductor layer are detectable in the second source/drain regions of the second semiconductor layer; and
a second gate structure over the second channel region of the second semiconductor layer.

17. The semiconductor device of claim 16, wherein the first gate structure is in contact with three sides of the first channel region, and the second gate structure is in contact with four sides of the second channel region.

18. The semiconductor device of claim 16, wherein the first semiconductor layer and the second semiconductor layer are made of different semiconductor materials.

19. The semiconductor device of claim 18, wherein:
the first gate structure comprises:
a first interfacial layer in contact with the first channel region;
a first high-k dielectric layer over the first interfacial layer;
a first work function metal layer over the first high-k dielectric layer; and
a first filling metal over the first work function metal layer; and
the second gate structure comprises:
a second interfacial layer in contact with the second channel region, wherein the first interfacial layer and the second interfacial layer are made of different materials;
a second high-k dielectric layer over the second interfacial layer;
a second work function metal layer over the second high-k dielectric layer; and
a second filling metal over the second work function metal layer.

20. The semiconductor device of claim 19, wherein the first work function metal layer and the second work function metal layer are made of a same material.
